(19) United States
(12) Patent Application Publication
(10) Pub. No.: US 2010/0309942 A1
(43) Pub. Date: Dec. 9, 2010

(54) Quantum Cascade Lasers (QCLs) Configured to Emit Light Having a Wavelength in the 2.5 - 3.8 Micrometer Band

(76) Inventor: Mikhail Belkin, Austin, TX (US)

Correspondence Address: FULBRIGHT & JAWORSKI L.L.P., 600 CONGRESS AVE., SUITE 2400, AUSTIN, TX, 78701, US

(21) Appl. No.: 12/791,587

(22) Filed: Jun. 1, 2010

Related U.S. Application Data
(60) Provisional application No. 61/184,363, filed on Jun. 5, 2009.

(51) Int. Cl. H01S 5/30; H01S 5/323; H01S 5/026; H01L 21/30

(52) U.S. Cl. 372/45.01; 438/31; 977/755; 257/E21.211

(57) ABSTRACT

Quantum cascade lasers (QCLs) with intra-cavity second-harmonic generation configured to emit light in the λ=2.5-3.8 μm band, and methods of use and manufacture.

### BACKGROUND OF THE INVENTION

1. Field of the Invention

The present invention relates generally to quantum cascade lasers (QCLs). More particularly, but not by way of limitation, the present invention relates to quantum cascade lasers configured to emit light in the 2.5-3.8 μm wavelength region.

2. Background Information

High-performance semiconductor lasers operating in the mid-infrared spectral range, λ=3.8-12 μm, may be important or useful in the areas of chemical sensing, direct infrared countermeasures, and free-space optical communications. See, e.g., Razeghi et al., 2008).

Currently, InGaAs/AlInAs/InP quantum cascade lasers (QCLs) are the only commercially available semiconductor lasers that can operate continuous-wave at room-temperature in most of the mid-infrared spectral range. QCLs are a generally new type of semiconductor lasers that are based on intersubband transitions between electron subbands in the conduction band in semiconductor superlattices, as illustrated conceptually in FIG. 1. Certain QCLs can be fabricated using InGaAs/AlInAs/InP materials, which may make their production compatible with telecommunication diode lasers production lines and thereby relatively cost efficient.

There are currently two major US manufacturers of mid-infrared QCLs: Maxion Technologies, Inc. and AdTech Optics, Inc. A number of US-based companies, including Daylight Solutions and Pranalytica, Inc., currently sell QCL products based on laser chips produced by others. Examples of international companies providing QCLs and QCL-based products include Swiss-based Alpes Lasers, Inc., UK-based Cascade Technologies, Inc., French-based Thales Group, and Japan-based Hamamatsu Photonics, Inc.

Due to the limited conduction band offset in InGaAs/AlInAs heterostructures, the performance of InGaAs/AlInAs/InP QCLs generally deteriorates at shorter wavelengths, even if strained structures are used. As a result, these devices typically can only operate at room-temperature at wavelengths 3.8-12 μm. As such, there is a lack of commercially-available room-temperature continuous-wave semiconductor lasers with a spectral range between 2.5-3.8 μm. In 2008, different types of semiconductor lasers were shown to be capable of continuous-wave operation at room-temperature in this region of spectrum (Canedy et al., 2008; Shterengas et al., 2008). However, these devices utilize Sb-based materials, which are generally not compatible with telecommunication laser diode materials, and may be extremely difficult and/or expensive to produce. As a result, the commercialization of these devices may be very challenging.

The idea of extending the spectral range of InGaAs/AlInAs/InP QCLs into 2.5-3.8 μm using Second Harmonic Generation (SHG) has been discussed in the past (e.g., in U.S. Pat. No. 6,816,530). However, only a few groups proposed solutions to improve the efficiency of SHG in QCLs to reach levels for practical applications. These previously proposed solutions have included: (1) using SHG with true phase matching in a QCL waveguide designed so that TM00 mode at the fundamental frequency ω has the same effective refractive index as TM02 mode at frequency 2ω (Malis et al., 2004; U.S. Pat. No. 6,940,639); (2) using surface-emission to extract non-phasematched SHG through the entire length of the device (Austerer et al., 2006); and (3) using quasi-phasematching by Stark shift of electronic resonances in the nonlinear active region of QCL (Belkin et al., 2006).

However, these solutions suffer from various problems that prevented their use for practical devices. In particular, solution 1 results in devices which are highly sensitive to the waveguide width (Malis et al., 2004). Further, these devices generate second-harmonic output in TM02 mode, while most applications required light output in TM00 mode. Solution 2 does not address the phase-matching problem and improves the SHG power by simply utilizing the whole length of the device as an emitter. As a result, the power output of the devices in U.S. Pat. No. 6,940,639 were limited to 150 μW (peak) in pulsed operation at T=80K (Austerer et al., 2006). Finally, the Stark shift of electronic resonances (solution 3) generally cannot produce efficient nonlinearity modulation for QPM because of the current spreading effect (Belkin et al., 2006).

The previous solutions (U.S. Pat. No. 6,816,530; Malis et al., 2004; U.S. Pat. No. 6,940,639; Austerer et al., 2006; Belkin et al., 2006) also proposed devices with optical nonlinearity integrated in the whole laser structure. QCLs with integrated optical nonlinearity generally have much worse wallplug efficiency, maximum operating temperature, and maximum output power, compared to optimized QCL structures without integrated optical nonlinearity. As a result, while state-of-the-art mid-infrared QCLs can operate in continuous-wave at and above room temperature to produce light in the range 3.8-12 μm; the devices in U.S. Pat. No. 6,816,530; U.S. Pat. No. 6,940,639; Austerer et al., 2006) only operate in pulsed mode at cryogenic temperatures.

### SUMMARY

The present disclosure includes various embodiments of quantum cascade lasers (QCLs), and methods for making and using QCLs. More particularly, but not by way of limitation, embodiments of the present QCLs are configured for emission at wavelengths 2.5-3.8 μm based on intra-cavity second-harmonic generation (SHG).

Mid-infrared QCLs may be used to develop product solutions in the areas of homeland security, military communications, infrared countermeasures, chemical warfare agent detection, explosives detection, medical diagnostics, industrial process controls, remote gas leak detection, pollution monitoring, and real-time combustion controls.

In particular, semiconductor lasers operating in the spectral range 2.5-3.8 μm may be highly desirable and/or useful for at least two major applications: bio/chemical sensing and direct infrared countermeasures. More specifically, in the chemical sensing area, the spectral range 2.5-3.8 μm contains most of the absorption lines that correspond to C-H stretching modes of simple hydrocarbon molecules and O-H stretching modes of water molecules and alcohols. As a result, this spectral range can be used for highly sensitive and specific detection of a number of hydrocarbons such as methane and formaldehyde (Werle and Popov, 1999). Regarding infrared countermeasures applications, semiconductor lasers in the 2.5-5 μm spectral range could improve and contribute to the efficacy of infrared missile decoys and suppression systems.

Because of the technological importance of the 2.5-3.8 μm spectral band, the commercial market potential for room-temperature QCLs with output at λ=3.0-3.8 μm is likely comparable to that for QCLs operating in the 3.8-12 μm band. Embodiments of the present QCLs and QCL configurations extend the spectral range of InGaAs/AlInAs/InP QCLs into the 2.5-3.8 μm band using quasi-phasematched intracavity second harmonic generation in QCLs that otherwise could have a wavelength between 5-7.6 μm. Embodiments of the present QCLs and methods can be manufactured or performed with relatively little modification to existing manufacturing devices and systems.

Embodiments of the present quantum cascade lasers have a length and an output facet, and comprise: a substrate; an active region coupled to the substrate; a feedback structure optically coupled to the active region and extending along at least a portion of the length of the laser; an SHG structure optically coupled to the active region and extending along only a portion of the length of the laser adjacent the output facet, the SHG structure comprising an optically nonlinear material; where the laser is configured such that if pumped with current, the laser will emit light having a wavelength between about 2.5 and about 3.8 micrometers (μm).

In some embodiments, the laser is configured such that if pumped with current: (a) the active region will produce light having a wavelength between about 5 μm and about 7.6 μm, and (b) the SHG structure will receive light emitted by the active region and will, by second harmonic generation, emit light having a wavelength that is one-half the wavelength of the light emitted by the active region. In some embodiments, the SHG structure comprises a grating configuration for quasi-phase matching of the second harmonic generation process. In some embodiments, the SHG structure comprises semiconductor quantum wells configured to have high optical nonlinearity for the second harmonic generation process associated with intersubband transitions.

In some embodiments, the active region comprises a plurality of alternating layers, each layer comprising one or more of at least two different material compositions. In some embodiments, the SHG structure comprises a grating having a first end and a terminal end, the first end facing away from the output facet of the laser, and the terminal end facing toward the output facet. In some embodiments, the feedback structure comprises a trench disposed apart from the output facet and extending through at least a portion of the active region, the trench perpendicular to the length of the laser and configured to provide light feedback to the active region, and the trench disposed farther away from the output facet than the first end of the SHG structure.

In some embodiments, the feedback structure comprises a distributed feedback (DFB) grating coupled to the active region. In some embodiments, the feedback structure comprises a distributed Bragg reflector (DBR) grating coupled to the active region. In some embodiments, the SHG structure is disposed on the feedback structure. In some embodiments, the SHG structure is disposed apart from the feedback structure. In some embodiments, the SHG structure has a length of between about 100 μm and about 1000 μm. In some embodiments, the SHG structure comprises InGaAs quantum wells and AlInAs quantum barriers. In some embodiments, one or more waveguide layers are coupled to the active region.

Some embodiments of the present methods of making a quantum cascade laser having a length and an output facet, comprise: coupling a feedback structure to an active region; and coupling an SHG structure to at least one of the feedback structure and the active region such that the SHG structure is optically coupled to the active region and extends along only a portion of the length of the laser adjacent the output facet, the SHG structure comprising an optically nonlinear material; where the active region, feedback structure, and SHG structure are configured such that, if the active region is pumped with current, the laser will emit light having a wavelength between about 2.5 and about 3.8 micrometers (μm).

In some embodiments, the active region, feedback structure, and SHG structure are configured such that if the active region is pumped with current: (a) the active region will produce light having a wavelength between about 5 μm and about 7.6 μm, and (b) the SHG structure will receive light emitted by the active region and will, by second harmonic generation, emit light having a wavelength that is one-half the wavelength of the light emitted by the active region.

In some embodiments, coupling an SHG structure comprises: depositing a layer of optically nonlinear material on at least one of the active region and the feedback structure; and removing a portion of the layer of optically nonlinear material to form a grating configuration. In some embodiments, coupling a feedback structure comprises: depositing a layer of material on the active region; and removing a portion of the layer of material to form a grating configuration.

In some embodiments, at least a portion of coupling (e.g., fabricating) a feedback structure is performed simultaneously with at least a portion of coupling (e.g., fabricating) an SHG structure (e.g., a quasi-phase matched grating). In some embodiments, the method further comprises: overgrowing an upper waveguide cladding on at least one of the active region, the feedback structure, and the SHG structure. In some embodiments, the feedback structure comprises a trench disposed apart from the output facet and extending through at least a portion of the active region, the trench perpendicular to the length of the laser and configured to provide light feedback to the active region, and the trench disposed farther away from the output facet than the first end of the SHG structure. In some embodiments, the feedback structure comprises a distributed feedback (DFB) grating coupled to the active region. In some embodiments, the feedback structure comprises a distributed Bragg reflector (DBR) grating coupled to the active region.

Any embodiment of any of the present methods can consist of or consist essentially of—rather than comprise/include/contain/have—any of the described steps, elements, and/or features. Thus, in any of the claims, the term “consisting of” or “consisting essentially of” can be substituted for any of the open-ended linking verbs recited above, in order to change the scope of a given claim from what it would otherwise be using the open-ended linking verb.

Details associated with the embodiments described above and others are presented below.

### BRIEF DESCRIPTION OF THE FIGURES

The following drawings illustrate by way of example and not limitation. For the sake of brevity and clarity, every feature of a given structure is not always labeled in every figure in which that structure appears. Identical reference numbers do not necessarily indicate an identical structure. Rather, the same reference number may be used to indicate a similar feature or a feature with similar functionality, as may non-identical reference numbers.

FIG. 1. Quantum cascade lasers. FIG. 1(a) depicts a microscope image of a QCL facet with zoomed-in inset showing the structure of the active region that comprises multiple InGaAs and AlInAs nanometer-thickness layers to define electron energy levels. The positions of the electron energy levels depend on the layer thicknesses. FIG. 1(b) depicts the band structure of tone stage of a QCL with relevant electron energy levels shown. Horizontal and vertical arrows show electron transport; wavy arrow shows photon emission. A typical mid-infrared QCL can have up to 50 stages. FIG. 1(c) depicts a processed 4 mm-long QCL mounted on a copper mount.

FIG. 2. Processing steps for the present QCLs and for traditional QCLs. FIGS. 2(a), 2(b), and 2(c) depict processing steps for making embodiments of the present single-mode DFB SHG QCLs for operation in the 2.5-3.8 μm spectral range using intra-cavity second harmonic generation in a small section near the device output facet. An InGaAs layer is introduced to allow the fabrication of a DFB grating, and it may have a thickness between 0.1-0.5 μm. FIGS. 2(d), 2(e), and 2(f) depict processing steps for traditional DFB QCLs for operation in the 3.8-12 μm band (for comparison). The upper waveguide cladding can be overgrown using, for example, metalorganic vapor phase epitaxy. The horizontal arrows indicate direction of the light output from devices.

FIG. 3. Processing steps for the present QCLs and for traditional QCLs. FIGS. 3(a), 3(b), and 3(c) depict processing steps for making embodiments of the present single mode DBR SHG QCLs for operation in the 2.5-3.8 μm spectral range using intra-cavity second harmonic generation in a small section near the device output facet. An InGaAs layer is introduced to help in fabrication of a strong DBR grating, either above or below the nonlinear layer, and it may have a thickness between 0-1 μm. FIGS. 3(d), 3(e), and 3(f) depict processing steps for traditional DBR QCLs for operation in the 3.8-12 μm band (for comparison). The upper waveguide cladding can be overgrown using metal organic vapor phase epitaxy. The horizontal arrows indicate the direction of the light output from the devices.

FIG. 4. Processing steps for the present QCLs. FIGS. 4(a), 4(b), and 4(c) depict side views of processing steps for making embodiments of the present multi-mode SHG QCLs for operation in the 2.5-3.8 μm spectral range using intra-cavity SHG in a small section near the device output facet.

FIG. 5. A front view of one embodiment of the present QCLs depicting several additional processing steps for the present QCLs including steps for forming an insulating layer, a top contact layer and a bottom contact layer.

FIG. 6 depicts the wavefunctions of the nonlinear section (SHG structure). Optical transitions ω₁=ω₂ (corresponding to the laser frequency) and ω_{SHG} (corresponding to the SHG frequency) may either be exactly in resonance with the transitions between the energy levels in the structure (depicted as wavy lines) or be off-resonant.

### DESCRIPTION OF ILLUSTRATIVE EMBODIMENTS

The term “coupled” is defined as connected, although not necessarily directly, and not necessarily mechanically; two items that are “coupled” may be integral with each other. The terms “a” and “an” are defined as one or more unless this disclosure explicitly requires otherwise. The terms “substantially,” “approximately,” and “about” are defined as largely but not necessarily wholly what is specified, as understood by a person of ordinary skill in the art.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system that “comprises,” “has,” “includes” or “contains” one or more elements possesses those one or more elements, but is not limited to possessing only those elements. Likewise, a method that “comprises,” “has,” “includes” or “contains” one or more steps possesses those one or more steps, but is not limited to possessing only those one or more steps. For example, in a system that comprises a light-cycle container and a dark-cycle container, the system includes the specified elements but is not limited to having only those elements. For example, such a system could also include a control unit.

Further, a device or structure that is configured in a certain way is configured in at least that way, but it can also be configured in other ways than those specifically described.

Second harmonic generation (SHG) is a nonlinear optical process in which photons at frequency ω are converted to frequency 2ω. SHG has been used in optics for frequency transformation, and conversion efficiencies of 50-85% can be obtained (Ou et al., 1992). In particular, the light source in green laser pointers is based on second-harmonic frequency conversion of an infrared laser radiation, λ=1064 nm (infrared)→532 nm (green), and may be more cost-efficient than green diode lasers.

SHG is a nonlinear optical process that occurs inside a medium with second-order nonlinear susceptibility χ_{eff}. In SHG, a portion of the laser radiation at frequency ω is converted into radiation at frequency 2ω. Assuming that optical conversion happens in a nonlinear medium of length L, and neglecting the depletion of the power of the pump wave (at frequency ω), the second harmonic power at the exit of the nonlinear medium is given by Equation 1 (Boyd, 2008):

$$W ( 2 ω = ω + ω ) ∝ {( {χ}_{eff} )}^{2} {( W ( ω ) )}^{2} {L}^{2} \times {( \frac{sin ( Δ k L / 2 )}{Δ k L / 2} )}^{2} , \qquad ( 1 )$$

where W(ω) and W(2ω) are the powers of beams at frequencies ω and 2ω, respectively. A parameter Δk is referred to as the phase mismatch for SHG and is given by Equation 2 (Boyd, 2008):

$$Δ k = k ( 2 ω ) - 2 k ( ω ) = \frac{2 ω n ( 2 ω )}{c} - 2 \frac{ω n ( ω )}{c} , \qquad ( 2 )$$

where k(ω), k(2ω), n(ω), and n(2ω)) are the wave vectors and refractive indices (or effective refractive indices in case of the propagation in a waveguide) of the beams at frequencies ω and 2ω, respectively. Typically, due to material dispersion, n(ω)≠n(2ω)) and ΔkL>>1. This can result in poor ω to 2ω conversion efficiency, as follows from Equation 1. For high conversion efficiency, Δk should be sufficiently small so that ΔkL<<1 and (sin(ΔkL/2)/(ΔkL/2))²≈1 in Equation 1.

Small values of Δk can be achieved either using materials in which n(ω)=n(2ω) (“true” phasematching) or using so-called quasi-phasematching (QPM) schemes or configurations (Boyd, 2008). In the latter case of QPM schemes or configurations, the optical nonlinearity in the nonlinear optical can be spatially modulated with a wavevector k_{QPM}=k(2ω)−2k(ω) (Boyd, 2008). The phase mismatch then becomes Δk=k(2ω)−2k(ω)−k_{QPM}=0 and Equation 1 becomes Equation 3 (Boyd, 2008):

W(2ω=ω+ω)∝(χ_{eff}(k_{QPM}))²(W(ω))²L², (3)

where χ_{eff}(k_{QPM}) is a spatial Fourier component of the nonlinear susceptibility d_{eff} modulated with a wavevector k_{QPM}.

In some embodiments, sections of the nonlinear layer are etched away to have QPM in the SHG structure. The value of k_{QPM} may be given by Equation 4.

$${k}_{QPM} = \frac{2 π}{Λ} = {k}_{2 ω} - 2 {k}_{ω} = \frac{2 π}{( \frac{λ}{2} )} ( {n}_{2 ω} - {n}_{ω} ) \qquad ( 4 )$$

Equation 5 shows the nonlinear response of the SHG structure. The SHG structure is a multi-quantum-well structure designed to have energy levels (“subbands”) such that the transitions between subbands are in resonance, or close to resonance, with the laser frequency and SHG frequency and have appropriate transition dipole moments to produce large nonlinear susceptibility χ⁽²⁾, as shown in the equation below:

$${χ}^{( 2 )} ( {ω}_{SHG} = 2 ω ) = \frac{1}{2 {ℏ}^{2} {ɛ}_{o}} {\sum }_{lmn} {N}_{i} \{ \begin{matrix}\frac{{μ}_{l n} {μ}_{n m} {μ}_{m l}}{[ \begin{matrix}( {ω}_{nl} - 2 ω ) - \\ i {Γ}_{nl}\end{matrix} ] [ \begin{matrix}( {ω}_{m i} - ω ) - \\ i {Γ}_{m l}\end{matrix} ]} \\ + \frac{{μ}_{l n} {μ}_{n m} {μ}_{m l}}{[ \begin{matrix}( {ω}_{nl} - 2 ω ) - \\ i {Γ}_{nl}\end{matrix} ] [ \begin{matrix}( {ω}_{m i} - ω ) - \\ i {Γ}_{m l}\end{matrix} ]}\end{matrix} \} \qquad ( 5 )$$

Here the summation goes over different subbands: ω is the laser frequency; ω_{SHG} is the SHG frequency; ωᵢⱼ, Γᵢⱼ, and μᵢⱼ are the transition frequency, linewidth broadening factor, and transition dipole moment, respectively, for an intersubband transition between states i and j; and Nᵢ is the electron population density in state i. The SHG frequency is exactly twice the pump frequency. With proper nonlinear section design, one may expect high fundamental light to SHG light conversion efficiencies. In particular, we estimate the value of the optical nonlinearity χ⁽²⁾ in the SHG section of 4×10⁴ pm/V and the conversion efficiency in the example structure discussed later to be about 2 mW/W².

When the transition energies in the SHG section are close to the laser frequency, the nonlinear section may have considerable optical absorption of the laser frequency. However, with proper nonlinear section design (such as that discussed below), optical absorption in the nonlinear section may only increase the threshold current density in the devices by approxiamately 30% compared to that in devices without the nonlinear section. In one embodiment, the threshold current density may further be lowered by placing a dichroic coating on the front laser facet with high reflectivity for fundamental light and low reflectivity for the SHG frequency.

In some embodiments, the present disclosure offers a way to (a) separate a section with optical nonlinearity (λ_{eff}) from the main pumping section in QCLs to provide additional feedback to the laser and reduce threshold current density and (b) achieve quasi-phasematching for the SHG process between TM00 waveguide modes at frequencies ω and 2ω (a TM00 mode emission is required for most applications). We note that one may also optimize the period of the quasi-phasematching grating in the nonlinear section to achieve high efficiency SHG between any type of laser mode (frequency ω) and any type of SHG mode (frequency 2ω). Moreover, the processing steps to produce the present QCLs with SHG frequency conversion are generally compatible with processing steps used to produce single-mode distributed feedback (DFB) and distributed Bragg reflector (DBR) lasers.

Relative to previously known devices, the present devices can be configured for 2ω output in TM00 mode. Further, the performance of the pump QCL (operating at frequency ω) of the present lasers should not experience significant deterioration because the nonlinear section (SHG structure) is separated from the pump laser section, and quasi phasematching (QPM) allows high SHG conversion efficiencies. Additional processing steps required to make the SHG structure and/or feedback structure are similar to that already used to fabricate traditional single-mode QCLs, and can be relatively inexpensive to implement.

The present devices can be configured to produce SHG output at λ=2.5-3.8 μm with power levels up to 100 mW (with optimized nonlinear structures), assuming a fundamental power of 3 W for λ=5.0-7.6 μm radiation. Thus, the present approach presents a simple and effective way to increase the spectral range of commercially available λ=3.8-12 μm QCLs to λ=2.5-3.8 μm spectral range with minimal active region and device processing modifications.

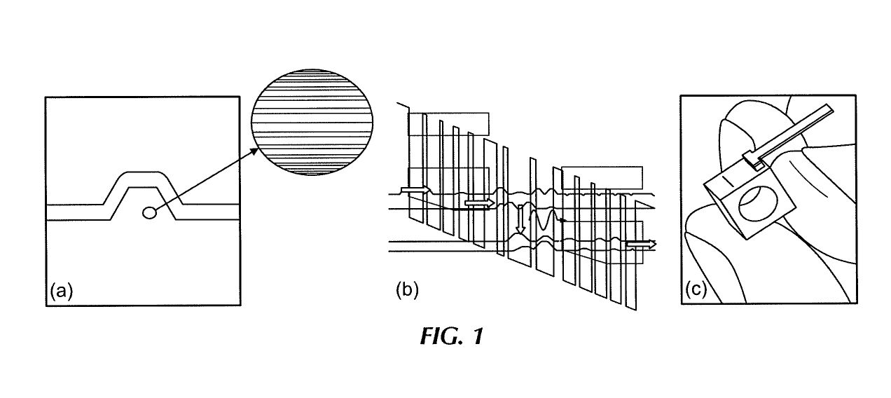

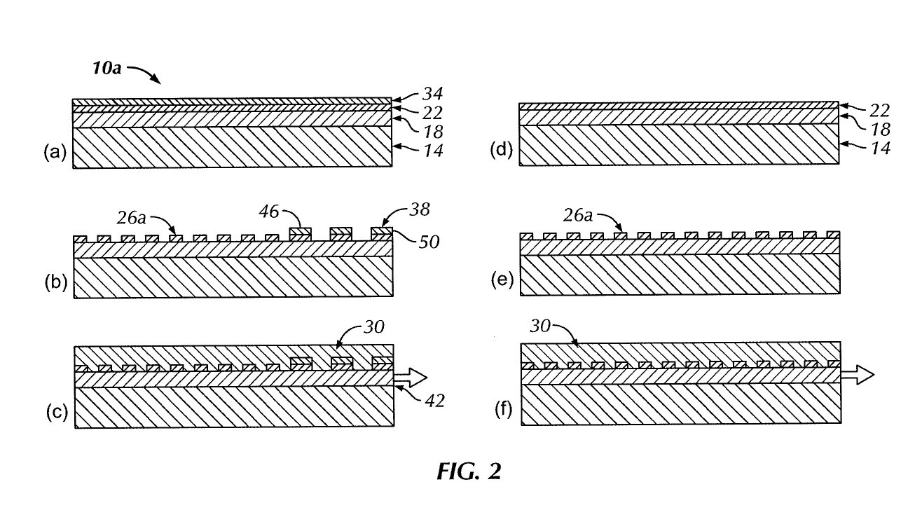

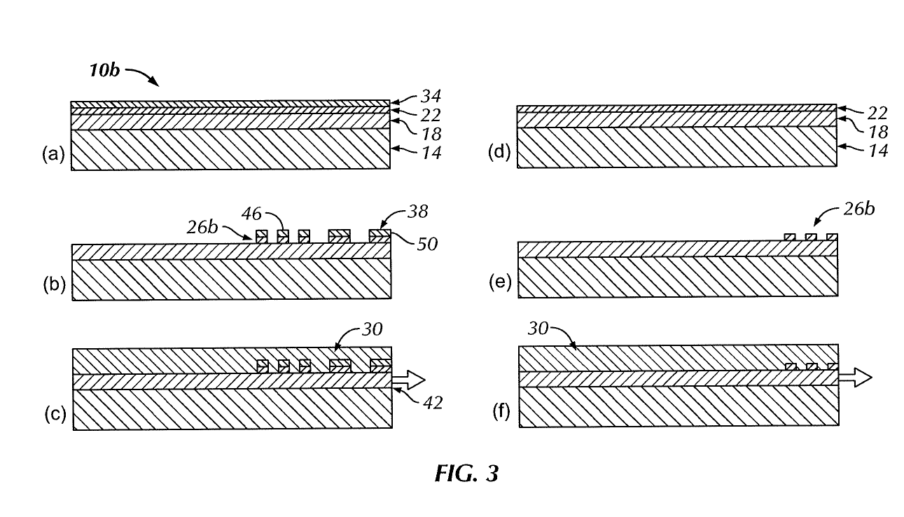

Referring now to the figures, the structure and the processing steps for making embodiments of the present SHG QCLs 10a and 10b for a single-mode TM00 emission in the 2.5-3.8 μm band are shown in FIGS. 2 and 3. In general, and as illustrated in FIG. 2(d)-2(f), the structure and method steps for making previous distributed feedback (DFB) QCLs 5 can include providing a substrate 14 having an active region 18 coupled to substrate 14 and a feedback layer 22 (e.g., comprising InGaAs) coupled to active region 18, as shown in FIG. 2(d); removing a portion of feedback layer 22 to form a feedback structure 26a, as shown in FIG. 2(e); and overgrowing an upper waveguide cladding 30 on at least one of active region 18 and/or feedback structure 26a. In various embodiments of the present QCLs, active region 18 can comprise a plurality of alternating layers, each layer comprising one or more of at least two different material compositions, such as, for example, as illustrated in the inset of FIG. 1(a). FIG. 1(a) shows an active region, as seen from the output facet.

Referring now to FIGS. 2(a)-2(c), 3(a)-3(e), and 4(a)-4(c), embodiments of the present QCLs may be formed in a manner or by a method that is similar in some respects to that of previously known QCLs. For example, QCL 10a has a length and an output facet 42, and comprises: a substrate 14; an active region 18 coupled to substrate 14; a feedback structure 26a optically coupled to active region 18 and extending along at least a portion (up to all) of the length of the laser; and an SHG structure 38 optically coupled to active region 18 and extending along only a portion of the length of the laser adjacent output facet 42. QCL 10a is further configured such that if pumped with current, the laser will emit light having a wavelength between about 2.5 and about 3.8 micrometers (μm). In particular, in the embodiment shown, QCL 10a is configured such that if pumped with current: (a) active region 18 will produce light having a wavelength between about 5 μm and about 7.6 μm with the feedback structure (e.g., DFB grating) providing optical feedback in the laser cavity, and (b) SHG structure 38 will receive light emitted by the active region and will, by second harmonic generation, emit light having a wavelength that is one-half the wavelength of the light emitted by the active region.

In some embodiments, the active region acts as the laser cavity, with one end of the cavity being the output facet 42 and the other end being the opposite end of the active region 18. In some embodiments, the QCL may operate in an external cavity configuration. In this embodiment, the back facet may have an antireflective coating which minimizes the reflection of the laser light back into the active region and have an external mirror or grating to provide feedback through the back facet.

In the embodiment shown, SHG structure 38 can be formed from a second harmonic generation (SHG) layer 34 coupled to (e.g., on top of) feedback layer 22 and/or an SHG structure 38 coupled to feedback structure 26a). More particularly, SHG layer 34 and/or SHG structure 38 can comprise a semiconductor multi-quantum-well layer with high optical nonlinearity associated with intersubband transitions (optically nonlinear material) coupled to active region 14 (e.g., via feedback layer 22 and/or feedback structure 26a). The optically nonlinear SHG layer can, for example, be designed or configured to have a large d_{eff} (e.g., λ_{eff}≈10⁵ pm/V) associated with intersubband transitions in asymmetric coupled AlInAs/GaInAs quantum wells (see, e.g., Sirtori et al., 1991). It may be noted that very large values of λ_{eff} (10⁵ pm/V) may be typical for devices based on intersubband transitions and that InGaAs/AlInAs superlattices have sufficient band offset to accommodate the nonlinear structures. A typical thickness of the SHG layer and/or SHG structure can be 0.1-0.5 μm; however the SHG layer and/or SHG structure layer can be thicker and/or thinner, depending on requirements of specific embodiments. During manufacturing, most of SHG layer 34 can be removed and only a small portion (approximately 100-1000 μm-long) left adjacent the output facet 42 of the laser 10a (the “SHG structure” or “SHG section”). The total length of the laser can be, for example, 2-4 mm or longer. In some embodiments, the length is 3 mm. This SHG section can also be patterned (e.g., in a grating pattern) to achieve quasi-phasematching for the SHG process between two TM00 modes (at frequencies ω and 2ω). In some embodiments, the grating patern has periods in the range of 20-40 μm, and/or the grating length is 100-1000 μm. In some embodiments, the width of the QCL, also known as the ridge width, is between 3 μm and 20 μm (e.g., 10 μm).

The SHG layer will generally be configured to strongly (e.g., substantially) absorb the radiation at the fundamental frequency ω (Sirtori et al., 1991). As a result, the SHG structure will have high absorption of the laser radiation at frequency ω and output facet 42 will provide reduced optical feedback (compared to the feedback provided by the output facet without the nonlinear section). To improve the otpical feedback from the output facet, embodiments of the present QCLs include a feedback structure, such as, for example, a distributed feedback (DFB) grating, a distributed Bragg reflector (DBR) grating, or the like. DFB or DBR gratings can, for example, be incorporated into the laser (e.g., coupled to the active region) prior to the SHG layer or SHG structure to produce sufficient feedback for the fundamental laser radiation. For example, feedback structure 26a of QCL 10a includes a DFB grating. The DFB and DBR gratings are also expected to provide single-mode (i.e. single laser frequency, ω) laser operation as required by some applications; in this case SHG output will also be single-mode (single frequency, 2ω). In one embodiment, the threshold current density may further be lowered by placing a dichroic coating on the front laser facet with high reflectivity for fundamental light and low reflectivity for the SHG frequency.

SHG structure 38 of QCL 10a comprises a grating configuration for quasi-phase matching of the second harmonic generation process. More particularly, SHG structure 38 of QCL 10a comprises semiconductor quantum wells configured to have high optical nonlinearity for the second harmonic generation process associated with intersubband transitions. In the embodiment shown, SHG structure 38 comprises a grating having a first end 46 and a terminal end 50, and first end 46 faces away from output facet 42 of QCL 10a, and terminal end 50 faces toward output facet 42 (and/or is flush or even with output facet 42). In the embodiment shown, the SHG structure can have a length of between about 100 μm and about 1000 μm (e.g., equal to, less than, greater than, and/or between, any of about: 200, 300, 400, 500, 600, 700, 800, 900, 1000 μm). The SHG structure can comprise, for example, InGaAs quantum wells and AlInAs quantum barriers. As shown for QCL 10a, feedback structure 26a can comprise a distributed feedback (DFB) grating coupled to the active region. As with previous QCLs, QCL 10a can further comprise one or more waveguide layers 30 coupled to the active region (e.g., directly and/or via the feedback structure and/or the SHG structure).

As shown in FIGS. 3(a)-3(c), QCL 10b is substantially similar to, and can be made in substantially similar fashion to, QCL 10a. As such, the differences in structure are primarily described here. QCL 10b also comprises a feedback structure 26b, but in the embodiment shown, feedback structure 26b comprises a distributed Bragg reflector (DBR) grating coupled to active region 18. In the embodiment shown, feedback structure 26b (DBR grating) does not extend the full length of the laser, and is formed (e.g., etched) through both feedback layer 22 and SHG layer 34. For QCL 10b, feedback structure 26b (DBR grating) is etched through both the feedback layer and the SHG layer; however, the SHG structure may be removed (e.g., etched away) from feedback structure 26b (e.g., such that the SHG structure does not overlap the feedback structure) or may extend along up to the full length of feedback structure 26b (e.g., to improve performance and/or efficiency and/or cost-effectiveness of manufacture). In QCL 10b, feedback layer 22 and SHG layer 34 can be interchanged (e.g., feedback layer 22 can be grown above SHG layer 34). Feedback structure 26b (DBR grating) is positioned farther away from the facet than the SHG structure 38 (which comprises a grating etched in the SHG layer 34, and possibly, but not necessarily, in the InGaAs feedback layer 22) to achieve quasi-phasematching for the SHG process.

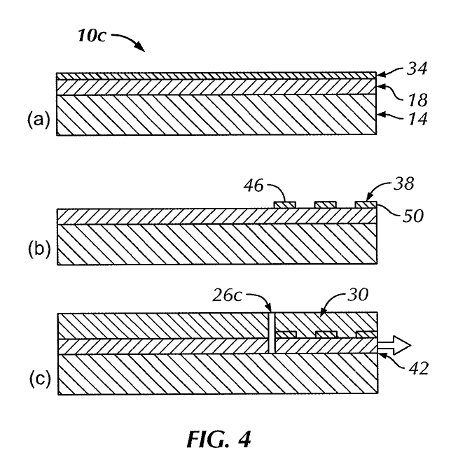

As shown in FIGS. 4(a)-4(c), QCL 10c is substantially similar to, and can be made in substantially similar fashion to, QCL 10a and/or QCL 10b. As such, the differences in structure are primarily described here. QCL 10c also comprises a feedback structure 26c, but in the embodiment shown, feedback structure 26c comprises a trench 26c disposed apart from output facet 42 and extending through at least a portion (up to all) of active region 18. The trench is perpendicular to the length of the laser and is configured to provide light feedback to the active region. In the embodiment shown, the trench defines the far end of the resonant cavity. In the embodiment shown, the trench is disposed farther away from output facet 42 than first end 46 of SHG structure 38. In the embodiment shown, SHG structure 38 is disposed apart from (not in direct contact with) feedback structure (trench) 26c.

The embodiment of FIG. 4, QCL 10c, may, for example, be useful if single-mode laser action is not required, and/or multi-mode (“Fabry-Perot”) operation is instead desired. With the trench feedback structure shown, the optical feedback from the right can be introduced by simply making a trench in the laser waveguide structure between the section of the laser without optical nonlinearity (without SHG structure 38) and the section of the laser with optical nonlinearity (with SHG structure 38). The trench will reflect part of the laser radiation generated in the left section so as to provide sufficient feedback to enable laser action. We note that, in some embodiments, the trench may not be required as the output facet would still provide enough optical feedback to start the laser, even if the SHG structure is present near the output facet.

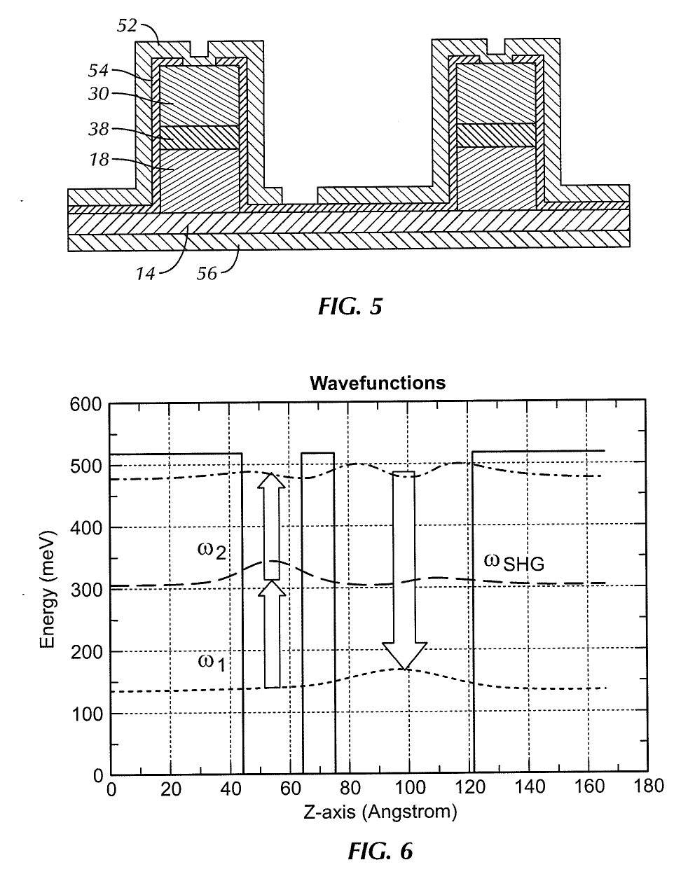

Referring now to FIG. 5, a front view is shown of two ridges, or QCLs. From the angle shown, light would exit the laser out of the page from active region 18. FIG. 5 also shows the front view of the SHG structure 38 and the cladding layer 30. This embodiment also shows an insulation layer 54, which may be SiN. In the embodiment shown, insulation layer 54 does not cover the entire top of cladding layer 30. Over the insulation layer is a top contact layer 52. Top contact layer 52 may comprise gold (Au) and/or titanium (Ti), and may, for example, be doposited using e-beam evaporation. In the embodiment shown, top contact layer 52 is able to contact cladding layer 30 through the gap in insulation layer 54. In this embodiment, substrate 14 has been polished or thinned and a bottom contact layer 56 has been attached. The backside contact may comprise Au and/or Ti. In operation of the embodiment shown, current is pumped through the laser by applying current to top contact layer 52 and bottom contact layer 56.

Embodiments of the present methods of making QCLs may share certain similarities, and will therefore be described together for various embodiments of QCLs. In some embodiments, the present methods of making a quantum cascade laser having a length and an output facet (e.g., 42), comprise: coupling a feedback structure (e.g., 26a, 26b, 26c) to an active region (e.g., 18); and coupling an SHG structure (e.g., 38) to at least one of the feedback structure (e.g., 26a, 26b, 26c) and the active region (e.g., 18) such that the SHG structure is optically coupled to the active region and extends along only a portion of the length of the laser adjacent or proximate to the output facet (e.g., 42), where the SHG structure comprises an optically nonlinear material; and where the active region, feedback structure, and SHG structure are configured such that, if the active region is pumped with current, the laser will emit light having a wavelength between about 2.5 and about 3.8 micrometers (μm). In some embodiments, the feedback structure increases the amount of light present in the wageguide. However, in some embodiments the feedback structure is not present. In some embodiments of the present methods, the active region, feedback structure, and SHG structure are configured such that if the active region is pumped with current: (a) the active region will produce light having a wavelength between about 5 μm and about 7.6 μm, and (b) the SHG structure will receive light emitted by the active region and will, by second harmonic generation, emit light having a wavelength that is one-half the wavelength of the light emitted by the active region.

In some embodiments of the present methods, coupling an SHG structure (e.g., 38) comprises: depositing a layer (e.g., SHG layer 34) of optically nonlinear material on at least one of the active region (e.g., 18) and the feedback structure (e.g., 26a, 26b, 26c), as illustrated in, e.g., FIG. 2(a); and removing a portion of the layer (e.g., SHG layer 34) of optically nonlinear material to form a grating configuration, as illustrated in, e.g., FIG. 2(b). In some embodiments, coupling a feedback structure (e.g., 26a, 26b, 26c) comprises: depositing a layer (e.g., 22) of material on the active region (e.g., 18), as illustrated in, e.g., FIG. 2(a); and removing a portion of the layer (e.g., 22) of material to form a grating configuration (e.g., DFB grating, DBR grating, etc.), as illustrated in, e.g., FIG. 2(b). In some embodiments, at least a portion of coupling a feedback structure (e.g., 26a, 26b, 26c) is performed simultaneously with at least a portion of coupling an SHG structure. For example, feedback layer 22 can be coupled to active region 18, SHG layer 34 can be coupled to feedback layer 22, and a portion of each can be simultaneously removed to form feedback structure 26a and SHG structure 38.

In some embodiments of the present methods, the feedback structure comprises a trench (e.g., 26c) disposed apart from the output facet (e.g., 42) and extending through at least a portion of the active region (e.g., 18), where the trench is perpendicular to the length of the laser and configured to provide light feedback to the active region, and where the trench is disposed farther away from the output facet than the first end (e.g., 46) of the SHG structure. Some embodiments of the present methods further comprise: overgrowing an upper waveguide cladding (e.g., 30) on at, least one of the active region, the feedback structure, and the SHG structure.

### EXAMPLE

The following Tables 1-5 describes one embodiment of the present QCLs designed to emit light at a wavelength of 3.6 μm. The total thickness of the active region in this example is 2.1769 μm. Table 1 is a high-level description of the structure. Tables 2-5 describe individual sections of the QCL in more detail.

TABLE 1
Overall QCL Structure

| Material/Section | Doping | Thickness | |
|---|---|---|---|
| InP | 3 × 10¹⁸ cm⁻³ | 5000 | Å |
| InP | 5 × 10¹⁶ cm⁻³ | 35000 | Å |
| InGaAs | 1 × 10¹⁷ cm⁻³ | 100 | Å |
| AlInAs | undoped | 30 | Å |
| AlInAs | 3 × 10¹⁷ cm⁻³ | 30 | Å |
| AlInAs | undoped | 30 | Å |
| (Ga,Al)InAs Nonlinear Section | | 24 × 167 | Å |
| GaInAs | 5 × 10¹⁶ cm⁻³ | 500 | Å |
| AlInAs | undoped | 24 | Å |
| (Ga,Al)InAs Active Region I | | 30 × 533 | Å |
| (Ga,Al)InAs Digital Grading II | | 307 | Å |
| GaInAs | 5 × 10¹⁶ cm⁻³ | 500 | Å |
| (Ga,Al)InAs Digital Grading I | | 250 | Å |
| Low-doped InP substrate | (preferably <2 × 10¹⁷) | | |

TABLE 2
Digital Grading I Layer

| Dopant Type | Material | Doping Level | Thickness |
|---|---|---|---|
| n | AlInAs | 1 × 10¹⁷ cm⁻³ | 5 Å |
| n | GaInAs | 1 × 10¹⁷ cm⁻³ | 45 Å |
| n | AlInAs | 1 × 10¹⁷ cm⁻³ | 10 Å |
| n | GaInAs | 1 × 10¹⁷ cm⁻³ | 40 Å |
| n | AlInAs | 1 × 10¹⁷ cm⁻³ | 15 Å |
| n | GaInAs | 1 × 10¹⁷ cm⁻³ | 35 Å |
| n | AlInAs | 1 × 10¹⁷ cm⁻³ | 20 Å |
| n | GaInAs | 1 × 10¹⁷ cm⁻³ | 30 Å |
| n | AlInAs | 1 × 10¹⁷ cm⁻³ | 25 Å |
| n | GaInAs | 1 × 10¹⁷ cm⁻³ | 25 Å |

TABLE 3
Digital Grading II Layer

| Dopant Type | Material | Doping Level | Thickness |
|---|---|---|---|
| i (intrinsic) | GaInAs | | 32 Å |
| i | AlInAs | | 18 Å |
| i | GaInAs | | 29 Å |
| i | AlInAs | | 19 Å |
| n | GaInAs | 3.0 × 10¹⁷ cm⁻³ | 26 Å |
| n | AlInAs | 3.0 × 10¹⁷ cm⁻³ | 20 Å |
| n | GaInAs | 3.0 × 10¹⁷ cm⁻³ | 25 Å |
| n | AlInAs | 3.0 × 10¹⁷ cm⁻³ | 22 Å |
| i | GaInAs | | 24 Å |
| i | AlInAs | | 27 Å |
| i | GaInAs | | 24 Å |
| i | AlInAs | | 41 Å |

TABLE 4
Active Region I (7.2 μm thick, two-phonon design)

| Dopant Type | Material | Doping Level | Thickness |
|---|---|---|---|
| i | GaInAs | | 32 Å |
| i | AlInAs | | 18 Å |
| i | GaInAs | | 29 Å |
| i | AlInAs | | 19 Å |
| n | GaInAs | 3.0 × 10¹⁷ cm⁻³ | 26 Å |
| n | AlInAs | 3.0 × 10¹⁷ cm⁻³ | 20 Å |
| n | GaInAs | 3.0 × 10¹⁷ cm⁻³ | 25 Å |
| n | AlInAs | 3.0 × 10¹⁷ cm⁻³ | 22 Å |
| i | GaInAs | | 24 Å |
| i | AlInAs | | 27 Å |
| i | GaInAs | | 24 Å |
| i | AlInAs | | 41 Å |
| i | GaInAs | | 16 Å |
| i | AlInAs | | 10 Å |
| i | GaInAs | | 53 Å |
| i | AlInAs | | 12 Å |
| i | GaInAs | | 51 Å |
| i | AlInAs | | 13 Å |
| i | GaInAs | | 47 Å |
| i | AlInAs | | 24 Å |

TABLE 5
Nonlinear Section

| Dopant Type | Material | Doping Level | Thickness |
|---|---|---|---|
| i | GaInAs | | 20 Å |
| i | AlInAs | | 11 Å |
| i | GaInAs | | 46 Å |
| i | AlInAs | | 30 Å |
| n | AlInAs | 3.0 × 10¹⁷ cm⁻³ | 30 Å |
| i | AlInAs | | 30 Å |

The various illustrative embodiments of lasers and methods described herein are not intended to be limited to the particular forms disclosed. Rather, they include all modifications, equivalents, and alternatives falling within the scope of the claims.

The claims are not intended to include, and should not be interpreted to include, means-plus- or step-plus-function limitations, unless such a limitation is explicitly recited in a given claim using the phrase(s) “means for” or “step for,” respectively.

### REFERENCES

The following references, to the extent that they provide exemplary procedural or other details supplementary to those set forth herein, are specifically incorporated herein by reference.
U.S. Pat. No. 6,816,530
U.S. Pat. No. 6,940,639
Austerer et al., Physica, E35:234-240, 2006.
Belkin et al., Appl. Phys. Lett., 88:201108, 2006.
Boyd, Nonlinear Optics, Academic Press, NY, 2008.
Canedy et al., J. Electron. Mat., 37:1780, 2008.
Malis et al., Appl. Phys. Lett., 84:2721, 2004.
Ou et al., Optics Lett., 17:640, 1992.
Razeghi et al., Optics and Photonics News, 19(7-8):42-47, 2008.
Shterengas et al., Appl. Phys. Lett., 93: 011103, 2008.
Sirtori et al., Appl. Phys. Lett., 59:2302, 1991.
Werle and Popov, Appl. Opt., 38:1494-1501, 1999.
Pallab Bhattacharya, Semiconductor Optoelectronic Devices, 2^{nd} Ed.

1. A quantum cascade laser having a length and an output facet, comprising:
a substrate;
an active region coupled to the substrate;
a feedback structure optically coupled to the active region and extending along at least a portion of the length of the laser;
an SHG structure optically coupled to the active region and extending along only a portion of the length of the laser adjacent the output facet, the SHG structure comprising an optically nonlinear material;
where the laser is configured such that if pumped with current, the laser will emit light having a wavelength between about 2.5 and about 3.8 micrometers (μm).

2. The laser of claim 1, where the laser is configured such that if pumped with current:
(a) the active region will produce light having a wavelength between about 5 μm and about 7.6 μm, and
(b) the SHG structure will receive light emitted by the active region and will, by second harmonic generation, emit light having a wavelength that is one-half the wavelength of the light emitted by the active region.

3. The laser of claim 1, where the SHG structure comprises a grating configuration for quasi-phase matching of the second harmonic generation process.

4. The laser of claim 3, where the SHG structure comprises semiconductor quantum wells configured to have high optical nonlinearity for the second harmonic generation process associated with intersubband transitions.

5. The laser of claim 1, where the active region comprises a plurality of alternating layers, each layer comprising one or more of at least two different material compositions.

6. The laser of claim 1, where the SHG structure comprises a grating having a first end and a terminal end, the first end facing away from the output facet of the laser, and the terminal end facing toward the output facet.

7. The laser of claims 1, where the feedback structure comprises a trench disposed apart from the output facet and extending through at least a portion of the active region, the trench perpendicular to the length of the laser and configured to provide light feedback to the active region, and the trench disposed farther away from the output facet than the first end of the SHG structure.

8. The laser of claim 1, where the feedback structure comprises a distributed feedback (DFB) grating coupled to the active region.

9. The laser of claims 1, where the feedback structure comprises a distributed Bragg reflector (DBR) grating coupled to the active region.

10. The laser of claim 1, where the SHG structure is disposed on the feedback structure.

11. The laser of claim 1, where the SHG structure is disposed apart from the feedback structure.

12. The laser of claim 1, where the SHG structure has a length of between about 100 μm and about 1000 μm.

13. The laser of claim 1, where the SHG structure comprises InGaAs quantum wells and AlInAs quantum barriers.

14. The laser of claim 1, further comprising:
one or more waveguide layers coupled to the active region.

15. A method of making a quantum cascade laser having a length and an output facet, the method comprising:
coupling a feedback structure to an active region; and
coupling an SHG structure to at least one of the feedback structure and the active region such that the SHG structure is optically coupled to the active region and extends along only a portion of the length of the laser adjacent the output facet, the SHG structure comprising an optically nonlinear material;
where the active region, feedback structure, and SHG structure are configured such that, if the active region is pumped with current, the laser will emit light having a wavelength between about 2.5 and about 3.8 micrometers (μm).

16. The method of claim 15, where the active region, feedback structure, and SHG structure are configured such that if the active region is pumped with current:
(a) the active region will produce light having a wavelength between about 5 μm and about 7.6 μm, and
(b) the SHG structure will receive light emitted by the active region and will, by second harmonic generation, emit light having a wavelength that is one-half the wavelength of the light emitted by the active region.

17. The method of claim 15, where coupling an SHG structure comprises:
depositing a layer of optically nonlinear material on at least one of the active region and the feedback structure; and
removing a portion of the layer of optically nonlinear material to form a grating configuration.

18. The method of claim 15, where coupling a feedback structure comprises:
depositing a layer of material on the active region; and
removing a portion of the layer of material to form a grating configuration.

19. The method of claim 15, where at least a portion of coupling a feedback structure is performed simultaneously with at least a portion of coupling an SHG structure.

20. The method of claim 15, further comprising:
overgrowing an upper waveguide cladding on at least one of the active region, the feedback structure, and the SHG structure.

21. The method of claim 15, where the feedback structure comprises a trench disposed apart from the output facet and extending through at least a portion of the active region, the trench perpendicular to the length of the laser and configured to provide light feedback to the active region, and the trench disposed farther away from the output facet than the first end of the SHG structure.

22. The method of claim 15, where the feedback structure comprises a distributed feedback (DFB) grating coupled to the active region.

23. The method of claim 15, where the feedback structure comprises a distributed Bragg reflector (DBR) grating coupled to the active region.
